(19) United States
(12) Patent Application Publication
(10) Pub. No.: US 2023/0282545 A1
(43) Pub. Date: Sep. 7, 2023

(54) Lidded Flip Chip Package Allowing for a Thermal Interface Material with Fluidity

(71) Applicant: YUCI SHEN, SAN JOSE, CA (US)

(72) Inventor: YUCI SHEN, SAN JOSE, CA (US)

(21) Appl. No.: 17/686,372

(22) Filed: Mar. 3, 2022

(51) Int. Cl. H01L 23/42; H01L 23/053; H01L 23/10

(52) U.S. Cl. CPC H01L 23/42; H01L 23/053; H01L 23/10

(57) ABSTRACT

The disclosure describes a lidded flip chip package, including a lid with a tray structure, wherein a tray is formed at an upper side of the lid, a heat spreader is mounted in the tray through a sealing ring so as to form a sealed gap between the tray and the heat spreader, another sealing ring is mounted at a lower side of the top piece of the lid so as to form another sealed gap between a flip chip and the lid, through-holes are formed through the tray so as to connect the first sealed gap with the second sealed gap, and a thermal interface material having fluidity is completely filled in the first sealed gap and at least partially filled in the second sealed gap. A lidded flip chip package including a lid with a two-step tray is one preferred embodiment of the present disclosure.

### TECHNICAL FIELD OF THE DISCLOSURE

The disclosure relates generally to a semiconductor chip package, and particularly to a lidded flip chip package to use a thermally conductive material with fluidity as its thermal interface material (TIM), especially including a liquid metal TIM.

### BACKGROUND OF THE DISCLOSURE

In a lidded flip chip package with a semiconductor chip being a heat-generating object, a thermal interface material (TIM) is usually used to fill the gap between the flip chip and the lid. The types of the TIM basically include thermal pad, thermal grease, phase change material and liquid metal. A good TIM needs to have 1) a high thermal conductivity, 2) a good surface wetting capability for reducing the thermal contact resistance, 3) a good gap filling capability, and 4) a good thermal reliability in test or application. A liquid metal as TIM usually includes gallium and gallium alloys. The melting point of the gallium is about 29.8° C., and that of gallium alloys are adjustable. The thermal conductivity of the liquid metal is much higher than the extensively used thermal pad or thermal grease. Furthermore, a liquid metal has much better capability for surface wetting and gap filling. So, of all the types of TIM, a liquid metal is an ideal TIM if only looking at the first three items. If a liquid metal can be used in a lidded flip chip package, the temperature of the lidded flip chip package can be reduced significantly as compared to other types of TIM. However, the conventional lidded flip chip packages based on a conventional lid of prior arts are limited to use a liquid metal as its TIM due to the pumping-out or leaking issue, that is, when the package is under a thermal cycling test or in its long term of application, the volume of the gap between the flip chip and the lid varies with temperature due to the warpage of the flip chip, causing the liquid metal TIM to pump out or leak. The TIM pumping-out or leaking issue will cause an incomplete gap filling between the flip chip and the lid, reducing the thermal performance of TIM. And the more important thing is that because a liquid metal is electrically conductive, a small amount of TIM pumping-out or leaking may damage the whole electronic device. As a result, it is a big challenge to commercially use a liquid metal type of TIM in a lidded flip chip package. A lidded flip chip package including a reservoir structure allowing for liquid TIM is disclosed in our recent invention, U.S. Pat. No. 10,643,924 B1. The present disclosure describes another lid for a lidded flip chip package to use a thermal interface material having fluidity, like a liquid metal.

### SUMMARY OF THE DISCLOSURE

A lid integrated with a tray structure and a lidded flip chip package based on the lid are described in the present disclosure so that a thermally conductive material having fluidity, like a liquid metal as an thermal interface material, can be efficiently and safely used in the lidded flip chip package. The basic features of the lidded flip chip package and the lid are summarized below.

A lidded flip chip package, comprising: a substrate, a flip chip mounted on the substrate, and a lid mounted on the substrate and over the flip chip; the lid including: a top piece with an upper side and a lower side, a foot, a tray with a bottom, a first sealing ring, a second sealing ring and a heat spreader; wherein the first sealing ring is mounted at the lower side of the top piece so as to form a first sealed gap between the flip chip and the lid; the tray is formed at the upper side and/or lower side of the top piece, in which the heat spreader is mounted; the second sealing ring is placed at a peripheral edge region between the heat spreader and the tray so as to form a second sealed gap between them; wherein a plurality of through-holes are formed through the bottom of the tray so as to connect the first sealed gap with the second sealed gap; and wherein a thermal interface material having fluidity is filled in the first sealed gap and the second sealed gap.

A lid allowing for a thermal interface material having fluidity in a lidded flip chip package, comprising: a top piece with an upper side and a lower side, a foot, a tray with a bottom, a first sealing ring, a second sealing ring and a heat spreader; wherein the tray is formed at the upper side of the top piece; the first sealing ring is mounted at the lower side of the top piece; and the heat spreader is mounted inside the tray through the second sealing ring as so as to form a sealed gap between the heat spreader and the tray; and a plurality of through-holes are formed in a portion of the bottom of the tray surrounded by the first sealing ring.

Some additional features of the lid and the lidded flip chip package of the present disclosure include that the tray is a two step tray or a double sided tray, the heat spreader includes a middle element and an extending wing, and others. These additional features and advantages of the embodiments of the present disclosure will become more apparent from the detailed descriptions in conjunction with the drawings below. The drawings and associated descriptions are to illustrate the embodiments of the present disclosure, not to limit the scope of what is claimed.

### BRIEF DESCRIPTION OF THE DRAWINGS

FIGS. 1, 1A, 1B, 1C and 1D are schematic diagrams for illustrating a lid allowing for a lidded flip chip package to use a thermal interface material having fluidity of one preferred embodiment of the present disclosure.

FIGS. 2 and 2A are schematic diagrams for illustrating a lid allowing for a lidded flip chip package to use a thermal interface material with fluidity of another preferred embodiment of the present disclosure.

FIGS. 3, 3A, 3B and 3C are schematic diagrams for illustrating a lid allowing for a lidded flip chip package to use a thermal interface material with fluidity of one preferred embodiment of the present disclosure.

FIGS. 4 and 4A are schematic diagrams for illustrating a lidded flip chip package with a thermal interface material having fluidity of a lidded flip chip package of one preferred embodiment of the present disclosure.

FIG. 5 is a schematic diagram for illustrating a ring-form notch and a piece of thermally conductive material further of a lidded flip chip package of one embodiment of the present disclosure.

FIG. 6 is a schematic diagram for illustrating one or more filling holes with plugs further included in a heat spreader of a lidded flip chip package of one embodiment of the present disclosure.

FIG. 7 is a schematic diagram for illustrating a pad on a rim of the tray and a plurality of thermally conductive elements vertically aligned in one or more of the plurality of through-holes so as to directly connect the flip chip with the heat spreader for a better thermal dissipation of a lidded flip chip package of one embodiment of the present disclosure.

FIG. 8 is a schematic diagram for illustrating a structure of a first sealing ring which seals a peripheral edge region at a top surface of a flip chip of a lidded flip chip package of one embodiment of the present disclosure.

FIG. 9 is a schematic diagram for illustrating another structure of a first sealing ring which seals a peripheral region at a top surface of a substrate around a flip chip of a lidded flip chip package of one embodiment of the present disclosure.

FIG. 10 is a schematic diagram for illustrating a plurality of through-holes arranged around a flip chip of a lidded flip chip package of one embodiment of the present disclosure.

FIGS. 11 and 11A are schematic diagrams for illustrating various types of foot of a lid or a lidded flip chip package of one embodiment of the present disclosure.

FIG. 12 is a schematic diagram for illustrating a pin-type of foot together with an adhesive as a first sealing ring of a lidded flip chip package of one embodiment of the present disclosure.

FIG. 13 is schematic diagram for illustrating a heat spreader with a middle element and an extending wing of a lid or a lidded flip chip package of one embodiment of the present disclosure.

FIG. 14 is a schematic diagram for illustrating a heat spreader including a separate middle element and a separate covering piece of a lid or a lidded flip chip package of one embodiment of the present disclosure.

FIGS. 15 and 15A are schematic diagrams for illustrating a double sided tray of a lid or a lidded flip chip package of one embodiment of the present disclosure.

FIG. 16 is a schematic diagram for illustrating a ring-form notch in an extending wing of a heat spreader and a tray having an opening for entirely exposing a flip chip of a lidded flip chip package of one embodiment of the present disclosure.

FIG. 17 is a schematic diagram for illustrating that the heat spreader is a heat sink or other cooling pieces and the second sealing ring is a rubber ring of a lidded flip chip package of one embodiment of the present disclosure.

### DETAILED DESCRIPTION OF THE PREFERRED EMBODIMENT

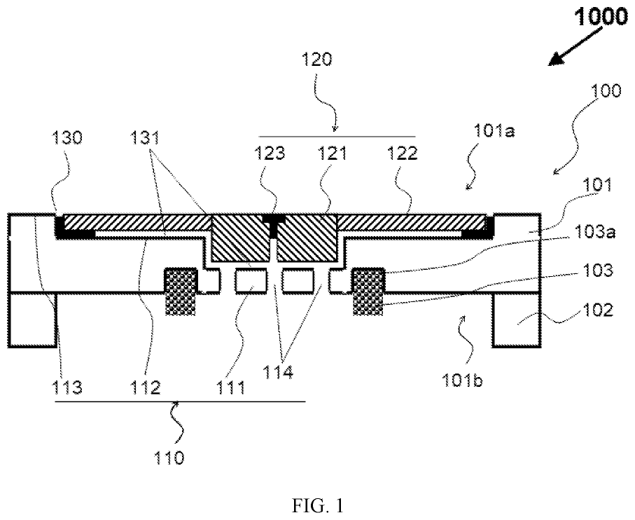

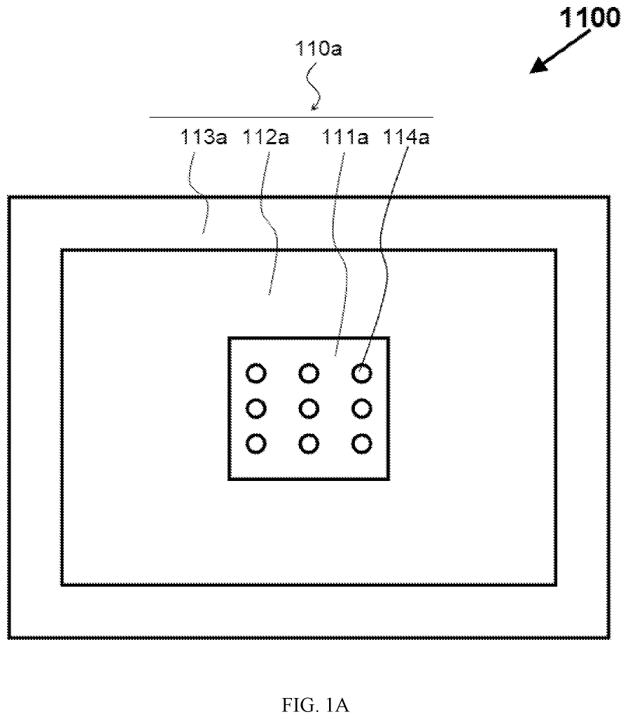

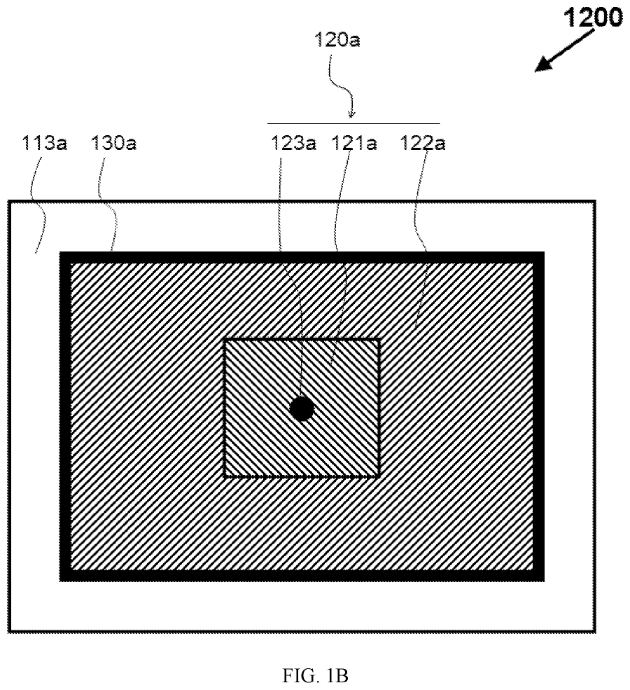

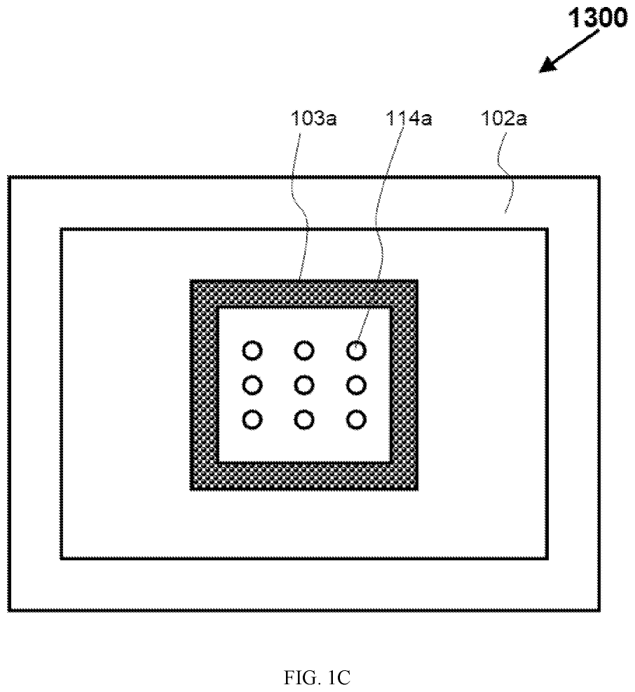

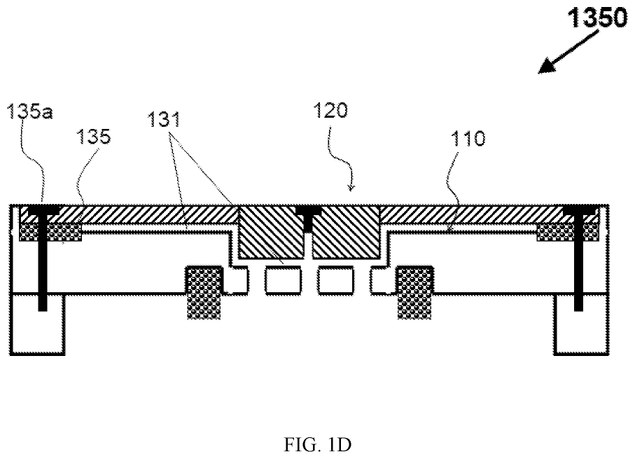

FIG. 1 is a schematic diagram for illustrating a lid allowing for a lidded flip chip package to use a thermal interface material having fluidity of one preferred embodiment of the present disclosure. The numerical symbol 1000 in FIG. 1 designates a cross-sectional view of a lid 100, comprising: a top piece 101 with an upper side 101a and a lower side 101b, a foot 102, a first sealing ring 103, a second sealing ring 130, a tray 110 and a heat spreader 120; wherein the tray 110 has a bottom 111/112 and a rim 113, which is formed at the upper side 101a of the top piece 101; the first sealing ring 103 is mounted at the lower side 101b of the top piece 101; and the heat spreader 120 is mounted inside the tray 110 through the second sealing ring 130, which also seals a peripheral edge region between the tray 110 and the heat spreader 120 so as to form a sealed gap 131 between them; and a plurality of through-holes 114 are formed through a portion 111 of the bottom 111/112 of the tray 110 inside the first sealing ring 103. The tray 110 illustrated in FIG. 1 is a two-step tray, whose bottom 111/112 includes a base-step portion 111 which is a portion of the bottom 111/112 inside the first sealing ring 103 and a second-step portion 112 which is a remaining portion of the bottom 111/112 mostly outside the first sealing ring 103. The heat spreader 120 illustrated in FIG. 1 includes a middle element 121 positioned over the base step portion 111, and an extending wing 122 positioned over the second step portion 112. As an option, the heat spreader 120 may include a filling hole with a plug 123 and the top piece 101 includes a ring-form notch 103a at its lower side 101b for mounting the first sealing ring 103. It is noted that the tray 110 is not limited to a two-step tray, which may have various configurations, for example, a regular tray with a flat bottom, a ring-form of tray or a double sided tray, which will be further depicted in conjunction with drawings later.

It is noted that if an element in a later figure is the same as one in a previous figure, the element will share the same numerical symbol as that in the previous figure, the same numerical symbol may not be marked out in the later figure and the same element may not be repeatedly described for simplicity and clarity.

FIGS. 1A, 1B and 1C are schematic diagrams for further illustrating the structure of the lid 100 illustrated in FIG. 1 from its top and bottom views. The numerical symbol 1100 in FIG. 1A designates a top view 110a of the tray 110 in FIG. 1, in which the numerical symbols 111a/112a, 113a and 114a respectively designate the top views of the bottom 111/112, the rim 113 and the plurality of through-holes 114 in FIG. 1. The numerical symbol 1200 in FIG. 1B designates a top view of the lid 100 in FIG. 1, in which the numerical symbol 120a designates the top view of the heat spreader 120 in FIG. 1, the numerical symbols 121a, 122a and 123a respectively designate the top views of the middle element 121, the extending wing 122, and the filling hole with a plug 123 of the heat spreader 120 in FIG. 1, and the 113a and 130a respectively designate the top views of the rim 113 and the second sealing ring 130 in FIG. 1. The numerical symbol 1300 in FIG. 1C designates the bottom view of the lid 100 in FIG. 1, in which the numerical symbols 102a, 103a and 114a respectively designate the bottom views of the foot 102, the first sealing ring 103 and the plurality of through-holes 114 in FIG. 1.

FIG. 1D is a schematic diagram for illustrating another structure of the second sealing ring 130 of the lid 100 illustrated in FIG. 1 of a lidded flip chip package of one preferred embodiment of the present disclosure. The numerical symbol 1350 in FIG. 1D designates the cross-sectional view of the lid, in which the numerical symbols 135 and 135a designate a rubber sealing ring and a plurality of screws, respectively. The screws 135a are used to tightly clamp the rubber sealing ring 135 at a peripheral edge region between the heat spreader 120 and the tray 110 so as to form the sealed gap 131 between the heat spreader 120 and the tray 110. A benefit of the structure of the second sealing ring is that the heat spreader can be easily replaced with a heat sink or a cooling piece in a field application of the lidded flip chip package.

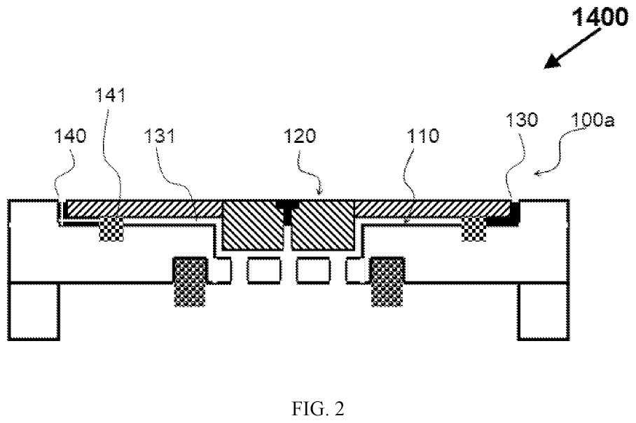

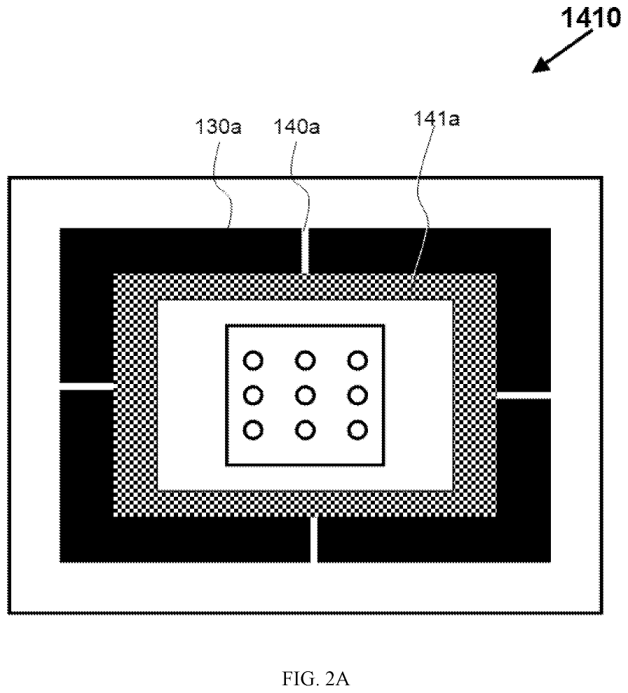

FIGS. 2 and 2A are schematic diagrams for illustrating some further features of the second sealing ring 130 of a lid 100a. The numerical symbol 1400 in FIG. 2 designates a cross-sectional view of the lid 100a, in which numerical symbol 140 designates one or more vents which are formed in the second sealing ring 130, and the 141 designates a filter ring which is arranged inside and adjacent to the second sealing ring 130. The numerical symbol 1410 in FIG. 2A designates the top view of the lid 100a, in which the heat spreader 120 in FIG. 2 is removed to show the second sealing ring 130a with the vents 140a and the filter ring 141a from their top views. A porous material or a mesh can be used for the filter ring 141/141a.

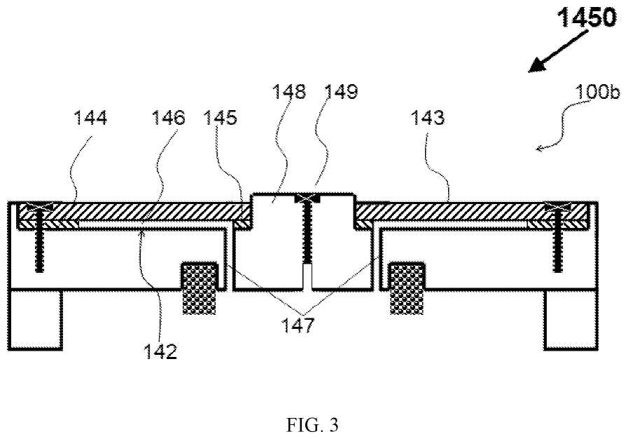

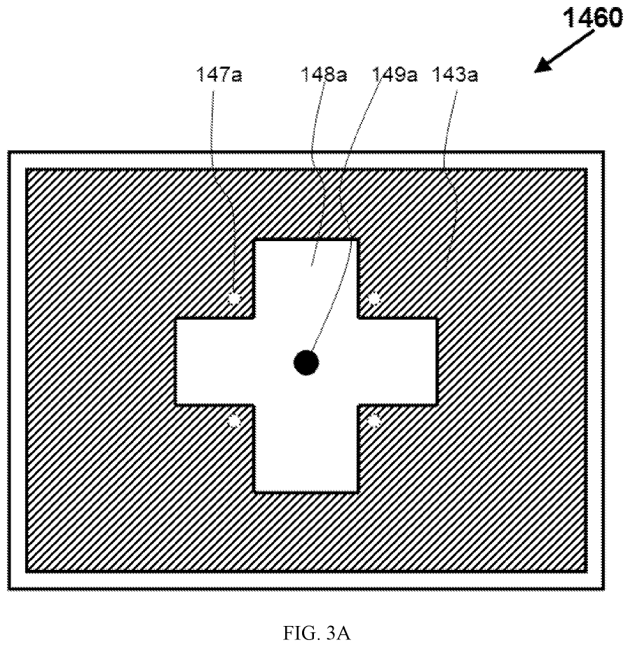

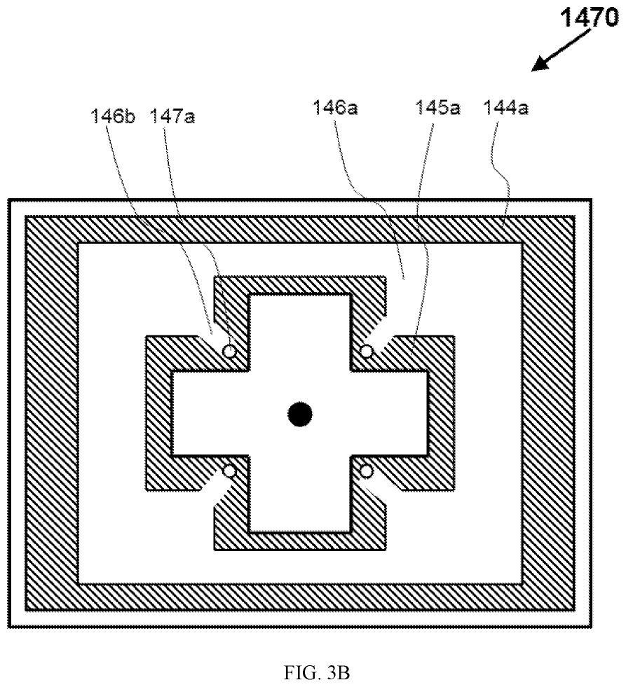

FIG. 3 is schematic diagram for illustrating a lid 100b with a ring-form of tray allowing for a lidded flip chip package to use a thermal interface material having fluidity of another preferred embodiment of the present disclosure. The numerical symbol 1450 in FIG. 3 designates a cross-sectional view of the lid 100b, in which the numerical symbol 142 designates a ring-form of tray formed in an upper side of the top piece of the lid, a ring-form of heat spreader as a covering piece 143 is mounted in the tray 142, a second sealing ring 144/145 including an outer ring 144 and an inner ring 145 is placed at a peripheral edge region between the ring-form of covering piece 143 and the ring-form of tray 142 so as to form a sealed gap 146, the numerical symbol 148 designates an island portion of the top piece of the lid, the 149 as an option designates a filling hole with a plug through the island portion 148, and a plurality of through-holes 147 are formed through the bottom of the tray 142.

FIGS. 3A, 3B and 3C are schematic diagrams for further illustrating the structure of the lid 100b illustrated in FIG. 3 from its top and bottom views. The numerical symbol 1460 in FIG. 3A designates a top view of the lid 100b lid in FIG. 3, the 143a designates a top view of the ring-form of covering piece 143, and the 148a designates a top view of the island portion 148, the 149a designates a top view of the filling hole with a plug 149, and the 147a designates the through-holes 147 below the ring-form of covering piece 143. The numerical symbol 1470 in FIG. 3B designates a top view of the lid 100b, where the ring-form of covering piece 143 is removed to show the second sealing ring 144/145 and the through-holes 147, in which the numerical symbol 144a/145a designates a top view of the second sealing ring 144/145, the 147a designates a top view of the through-holes 147, and the 146a/146b designates a top view of the sealed gap 146. The numerical symbol 1480 in FIG. 3C designates a top view of the lid 100b in FIG. 3, in which the numerical symbol 201 designates a plurality of screws as an option for mounting the ring-form of covering piece 143/143a in the ring-form of tray 142. It is noted that the material for the second sealing ring can be an adhesive material or a rubber material, and the structure of the second sealing ring can be flexibly designed. When a rubber material is used for the second sealing ring, a screw is used for clamping the second sealing ring at a peripheral edge region between the heat spreader and the tray.

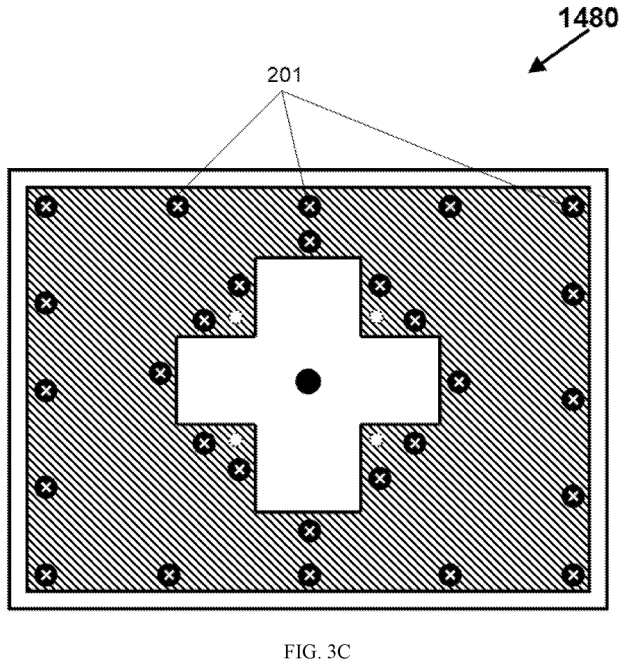

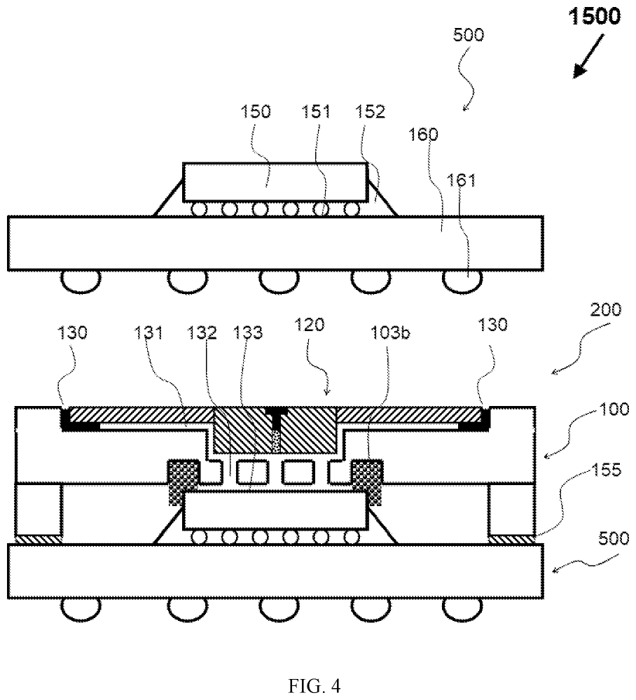

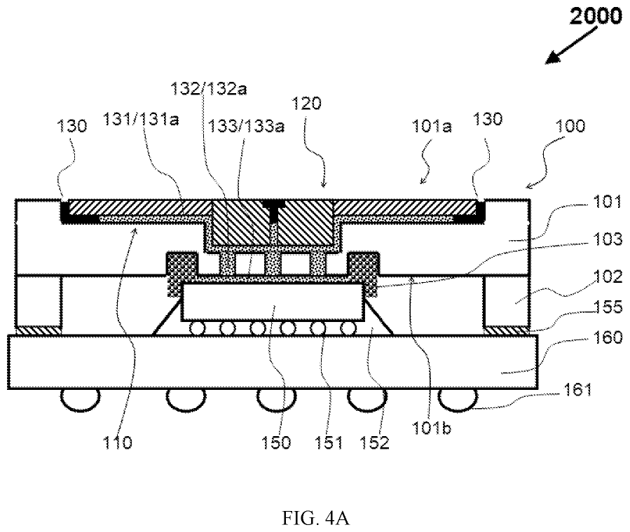

FIGS. 4 and 4A are schematic diagrams for illustrating a lidded flip chip package of one preferred embodiment of the present disclosure. The numerical symbol 1500 in FIG. 4 illustrates to attach a present lid with a flip chip package, in which the numerical symbols 500 designates a traditional flip chip package, including a substrate 160, a flip chip 150 mounted on the substrate 160, the 161 designates solder balls at the bottom of the substrate 160, which may be pins or pads for other types of flip chip packages; the 151 and 152 designate bumps and underfill material for electrically and mechanically connecting the flip chip 150 with the substrate 160; and in which the numerical symbols 200 designates that the lid 100 as described in FIG. 1 is mounted on the substrate 160 and over the flip chip 150 of the flip chip package 500, the 155 designates an adhesive which bonds the foot 102 of the lid 100 as showed in FIG. 1 to a peripheral region on a top surface of the substrate 160, the 103b designates a deformed sealing ring of the sealing ring 103 as described in FIG. 1, which seals a peripheral edge region at a top surface of the flip chip 150 so as to form a sealed gap 133 between the flip chip 150 and the lid 100. To clearly describe a lidded flip chip package of the present disclosure, the sealed gap 133 between the flip chip 150 and the lid 100 is called a first sealed gap, and the sealed gap 131 in the lid 100 as described in FIG. 1 is relatively called a second sealed gap. The through-holes 132 connect the first sealed gap 133 with the second sealed gap 131.

The numerical symbol 2000 in FIG. 4A designates a lidded flip chip package of one preferred embodiment of the present disclosure, comprising: a substrate 160, a flip chip 150 mounted on the substrate 160, and a lid 100 mounted on the substrate 160 and over the flip chip 150; the lid 100 including: a top piece 101 with an upper side 101a and a lower side 101b, a foot 102, a tray 110 with a bottom, a first sealing ring 103, a second sealing ring 130 and a heat spreader 120; wherein the first sealing ring 103 is mounted at the lower side 101b of the top piece 101 so as to form a first sealed gap 133 between the flip chip 150 and the lid 100; the tray 110 is formed at the upper side 101a of the top piece 101, in which the heat spreader 120 is mounted; the second sealing ring 130 is placed at a peripheral edge region between the heat spreader 120 and the tray 110 so as to form a second sealed gap 131 between them; wherein a plurality of through-holes 132 are formed through the bottom of the tray 110 so as to connect the first sealed gap 133 with the second sealed gap 131; and wherein a thermal interface material 133a, 132a and 131a having fluidity is completely filled in the first sealed gap 133 and at least partially filled in the second sealed gap 132. It is noted that though the thermal interface material is also completely filled in the second sealed gap 131 in the embodiment as showed in FIG. 4A, it can be partially filled in the second sealed gap 131 as another option.

It is noted that the tray 110 described in the lid 100 in FIG. 1 or the lidded flip chip package 2000 in FIG. 4A is a two-step tray, whose bottom 111/112 includes a base-step portion 111 as a portion of the bottom inside the first sealing ring 103 and a second-step portion 112 as a portion of the bottom outside the first sealing ring, and the heat spreader 120 includes a middle element 121 positioned over the base step portion 111 and an extending wing positioned over the second step portion 112. And a lidded flip chip package with a lid having a ring-form of tray as described in FIG. 3 is another preferred embodiment of the present disclosure, wherein the heat spreader is accordingly a ring-form of covering piece, which is mounted in the ring-form of tray so as to form a second sealed gap.

It is explained that the working mechanism for the lidded flip chip package 2000 as described in FIG. 4A to use a thermal interface material with fluidity 133a and 131a is that the heat spreader 120 can be designed to move or deform upwards or downwards against the volume change of the first sealed gap 133 due to the warpage behavior of the flip chip 150. For example, the extending wing 122 of the heat spreader 120 can be designed to be flexible, which can deform so that the middle element 121 of the heat spreader 120 can move upwards or downwards. It is noted that the second sealed gap 131 doesn't have to be completely filled with the thermal interface material with fluidity 131a, and a peripheral portion of the second sealed gap 131 outside the first sealing ring can be kept empty and filled with a gas. In such a way, the expansion or shrinkage of the gas can accommodate the volume change of the first sealed gap 133 so that the first sealed gap 133 can be completely filled with the thermal interface material with fluidity 131a all the time.

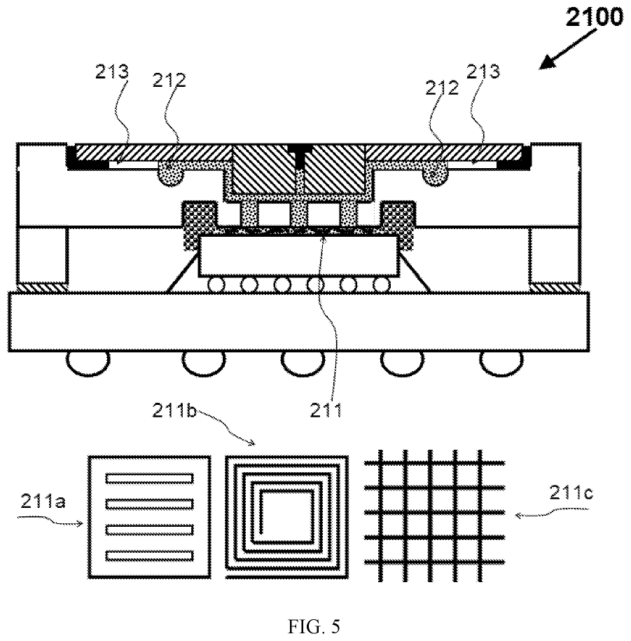

FIG. 5 is a schematic diagram for illustrating some further features, including a ring-form of notch and a piece of thermally conductive material in a lidded flip chip package of one embodiment of the present disclosure. The numerical symbol 2100 in FIG. 5 designates a lidded flip chip package of one preferred embodiment of the present disclosure, in which the 212 designates a ring-form of notch at an upper side of the bottom of the tray and around the first sealing ring, the 213 designates an empty region at an outmost peripheral region of the second sealed gap, and the 211 designates a piece of thermally conductive material in the first sealed gap, including a sheet with a plurality of through-holes or slots 211a, a pattern of wire 211b and a mesh 211c. It is noted that the ring-form of notch 212 can store more liquid thermal interface material in the second sealed gap for better accommodating the volume change of the first sealed gap due to the warpage behavior of the flip chip, the empty region 213 can be filled with a gas to form a gas pressure for keeping the first sealed gap to be completely filled with a liquid thermal interface material all the time, and the piece of thermally conductive material 211 can control the thickness of the first sealed gap and improve the thermal conductivity of the thermal interface material in the first sealed gap.

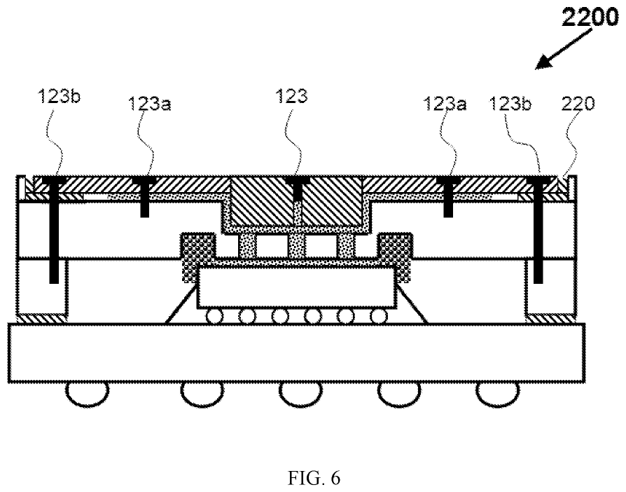

FIG. 6 is a schematic diagram for illustrating one or more filling or fixing holes with plugs, like screws arranged through the heat spreader. The numerical symbol 2200 in FIG. 6 designates a lidded flip chip package with one or more filling or fixing holes with plugs, like screws, 123, 123a and/or 123b, wherein the holes with plugs 123 and/or 123a are used for filling a liquid thermal interface material into the first and second sealed gaps, which can also be used to withdraw the liquid outside the gaps when needed, and the holes with screws 123b are used for further keeping the heat spreader in place so that a rubber material 220 can be used for the second sealing ring.

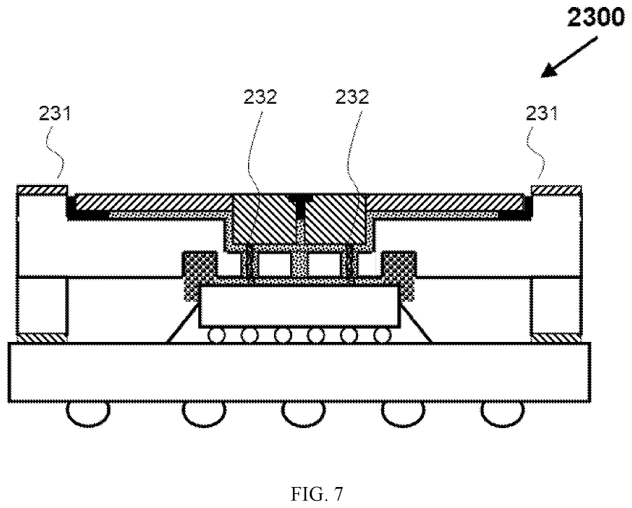

FIG. 7 is a schematic diagram for illustrating a pad on a rim of the tray and a plurality of thermally conductive elements vertically aligned in one or more of the plurality of through-holes so as to directly connect the flip chip with the heat spreader for a better thermal dissipation in a lidded flip chip package of one embodiment of the present disclosure. The numerical symbol 2300 in FIG. 7 designates a lidded flip chip package, in which the 231 designates a pad as a buffer arranged on the rim of the tray so as to avoid an external force, like the force from a heat sink to directly apply onto the heat spreader, and the 232 designates a plurality of thermally conductive elements vertically aligned in one or more of the plurality of through-holes so as to directly connect the flip chip with the heat spreader for a better thermal dissipation.

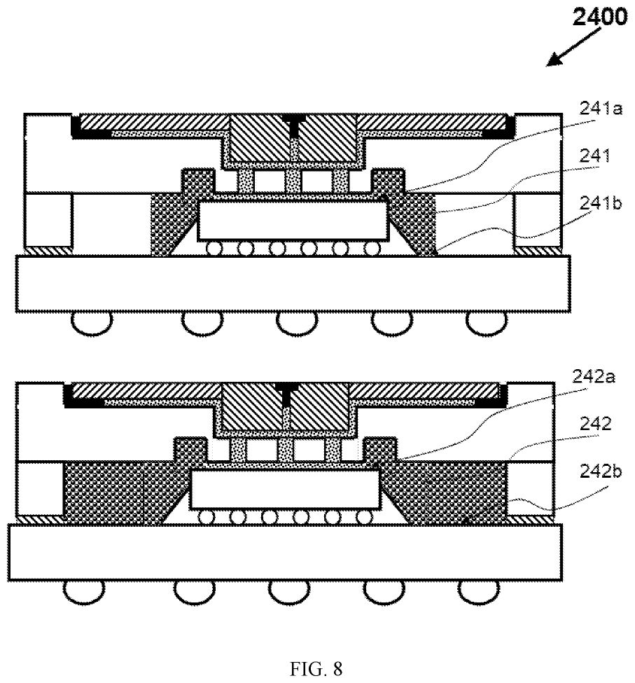

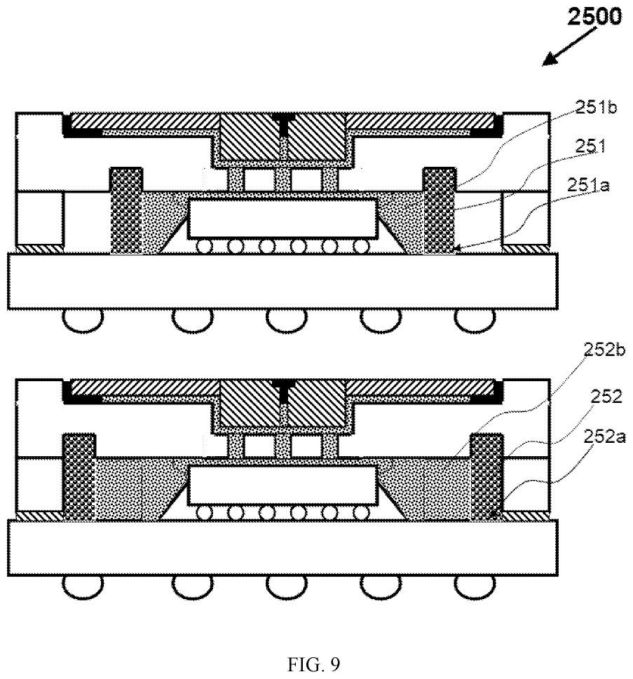

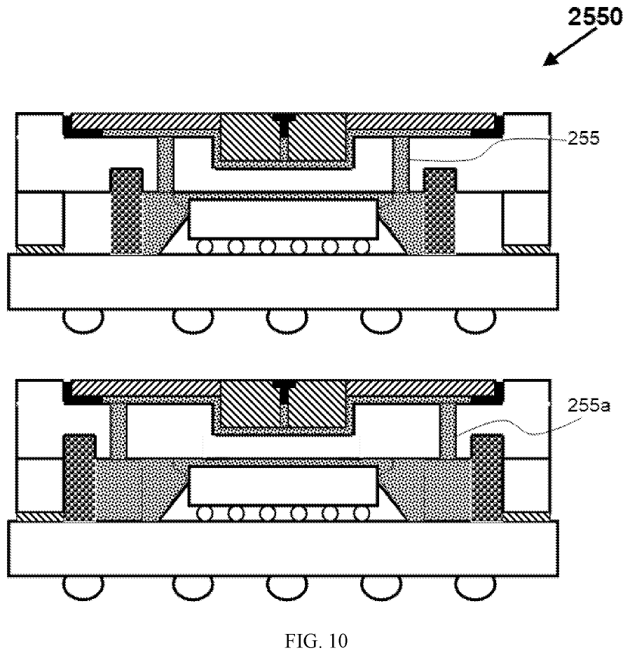

FIG. 8, FIG. 9 and FIG. 10 are schematic diagrams for illustrating the various designs for the structure of the first sealing ring. The numerical symbol 2400 in FIG. 8 designates a lidded flip chip package of one embodiment of the present disclosure, wherein the first sealing ring seals a peripheral edge region 241a/242a at a top surface of the flip chip of the lidded flip chip package, in which the numerical symbols 241 and 242 designate two structures of the first sealing ring, which also seal a peripheral region 241b/242b at a top surface of the substrate around the flip chip. The numerical symbol 2500 in FIG. 9 designates a lidded flip chip package of one embodiment of the present disclosure, wherein the first sealing ring 251 or 252 seals a peripheral region 251a or 251a around the flip chip at a top surface of the substrate so that the first sealed gap also includes a cavity 251b or 252b around the flip chip. The numerical symbol 2550 in FIG. 10 designates a lidded flip chip package of one embodiment of the present disclosure, wherein the connecting holes 255 or 255a are arranged in the region of the cavity around the flip chip.

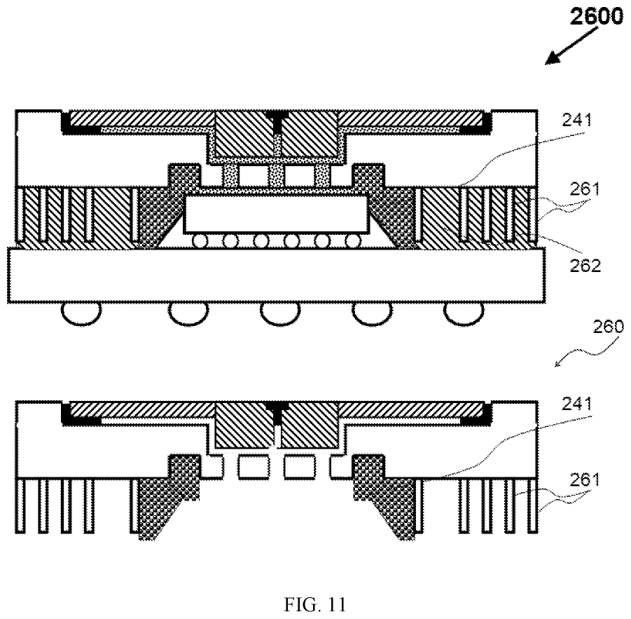

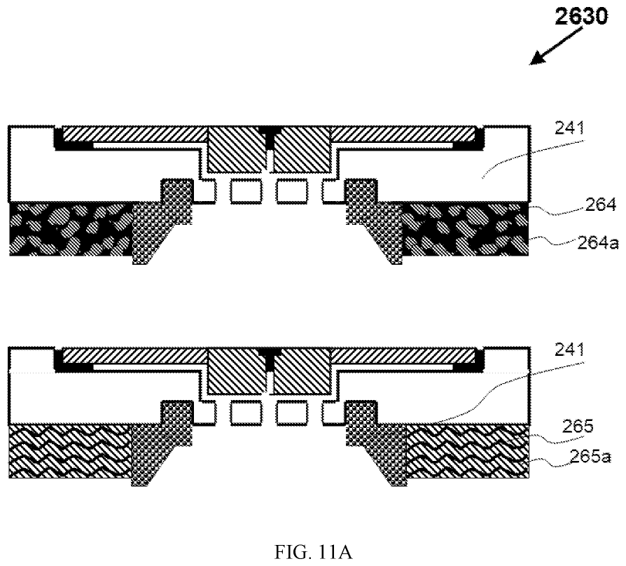

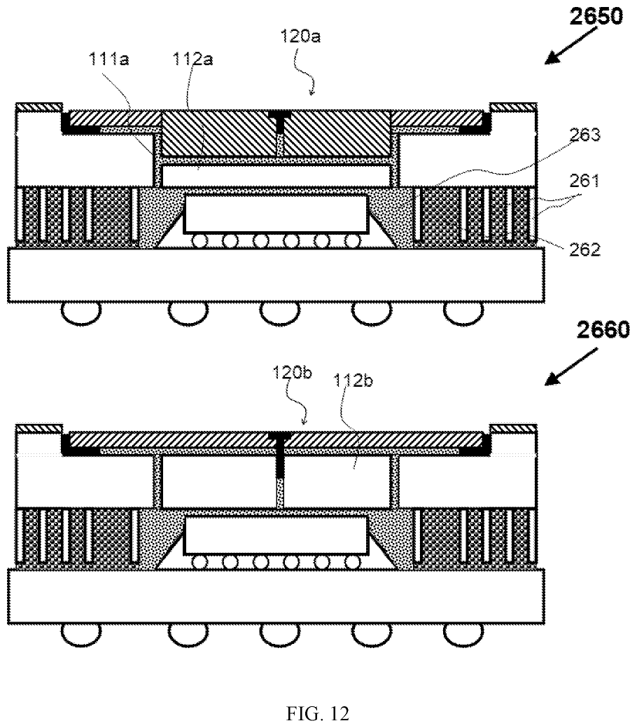

FIG. 11 and FIG. 12 are schematic diagrams for illustrating various types of foot of a lid or a lidded flip chip package of one embodiment of the present disclosure. The numerical symbol 2600 in FIG. 11 designates a lidded flip chip package of one embodiment of the present disclosure, in which the numerical symbol 241 designates the first sealing ring as described in previous FIG. 8, a pin-type of foot 261 together with an adhesive 262 bonds the lid 260 on a peripheral region at a top surface of the substrate and encloses the first sealing ring 241. The numerical symbol 2630 in FIG. 11A illustrates that the foot of the lid consists of a piece of impregnated porous material or mesh with an adhesive or resin, including a pre-impregnated fiberglass, in which the 264 and 264a designate a piece of impregnated porous material consisting of a porous matrix 264 pre-impregnated with an adhesive or a resin 264a, and the 265 and 265a designate a piece of impregnated mesh consisting of a mesh as a matrix 265 pre-impregnated with an adhesive or a resin 264a, including a pre-impregnated fiberglass. The types of foot pre-impregnated with an adhesive or resin can form a sealing ring, which can be used to replace the first sealing ring 241 or to further improve the sealing safety. The numerical symbols 2650 and 2660 in FIG. 12 designate schematic diagrams for illustrating a lidded flip chip package of one embodiment of the present disclosure, in which a pin-type of foot 261 together with an adhesive 262 is used as a first sealing ring, the numerical symbol 263 designates a first sealed gap, which also includes a cavity around the flip chip, the 111a designates a plurality of through-holes for connecting the first sealed gap 263 with the second sealed gap 264, the 112a and 112b respectively designate the bottom of a two-step tray and the bottom of a regular tray, and the 120a and 120b respectively designate a heat spreader with a middle element and a covering piece as a heat spreader.

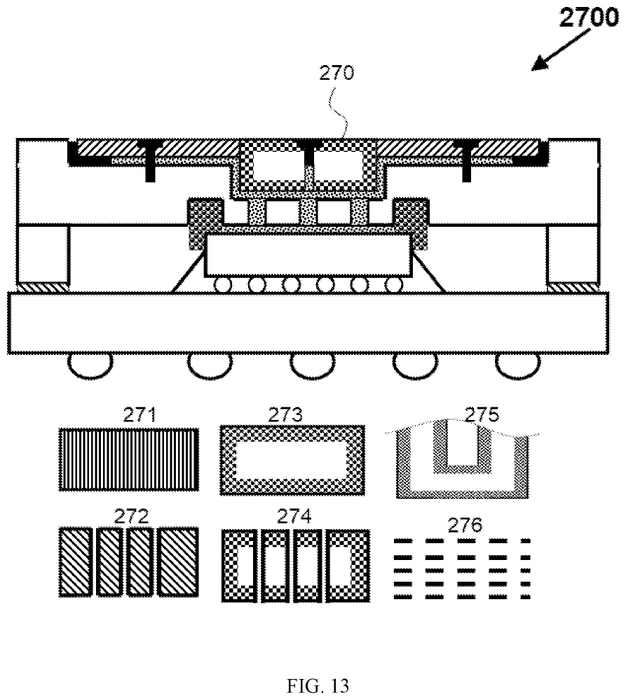

FIG. 13 is schematic diagram for illustrating a heat spreader with a middle element and an extending wing of a lid or a lidded flip chip package. The numerical symbol 2700 in FIG. 13 designates a lidded flip chip package of one embodiment of the present disclosure, in which the numerical symbol 270 designates a vapor chamber as the middle element, which can be flexibly designed, and the numerical symbols 271 to 276 designate various middle elements, including a high thermal conductive block 271, a high thermal conductive block with through-holes 272, a vapor chamber 273, a vapor chamber with through-holes 274, a heat pipe 275 and a thermal conductive mesh 276.

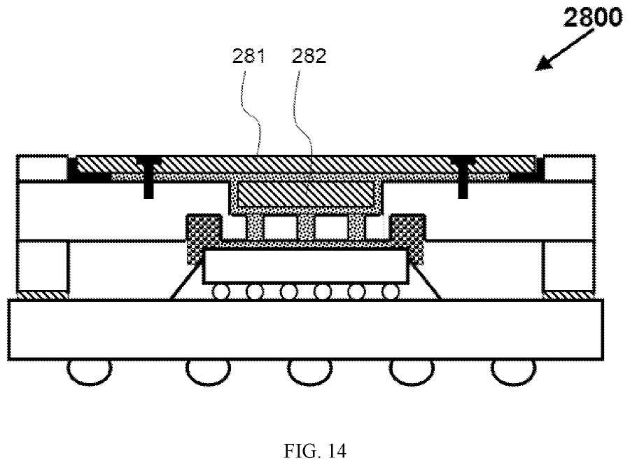

FIG. 14 is a schematic diagram for illustrating a heat spreader with a separate middle element and a separate covering piece of a lidded flip chip package. The numerical symbol 2800 in FIG. 14 designates a lidded flip chip package of one embodiment of the present disclosure, in which the numerical symbols 282 and 281 designates a separate middle element and a separate covering piece of a heat spreader mounted in the two-step tray. The separate middle element and the separate covering piece can be flexibly designed in their materials and structures.

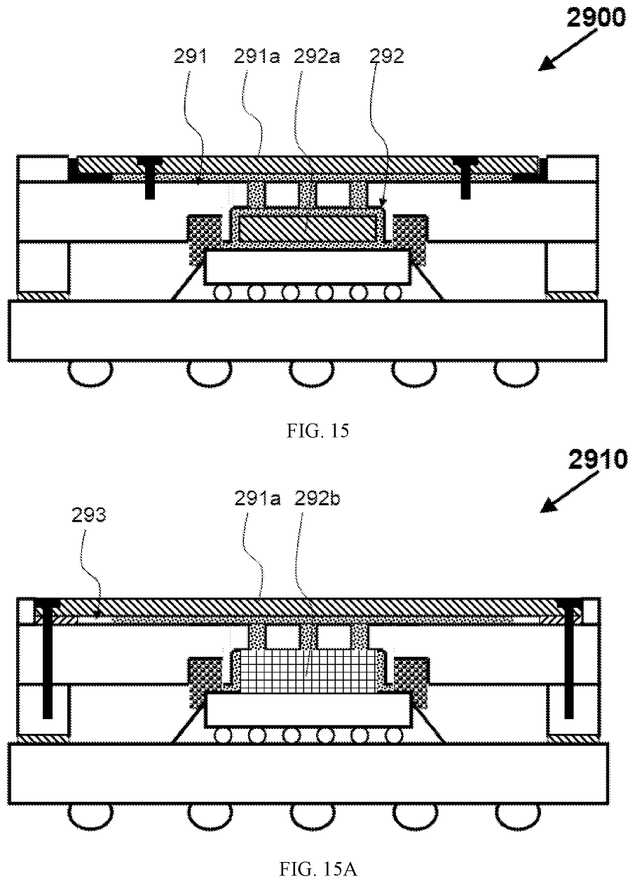

FIG. 15 is a schematic diagram for illustrating a double sided tray of a lid or a lidded flip chip package. The numerical symbol 2900 in FIG. 15 designates a lidded flip chip package of one embodiment of the present disclosure, in which the numerical symbols 291 and 292 respectively designate an upper tray and a lower flipped tray of a double sided tray formed in the top piece of the lid, and the 291a and 292a respectively designate a covering piece and a thermally conductive block mounted in the upper tray 291 and the lower flipped tray 292. FIG. 15A is a schematic diagram for illustrating some further features of the lidded flip chip package as showed in FIG. 15, in which the numerical symbol 292b designate a thermally conductive mesh directly contacting with the flip chip and the tray, and the 293 illustrates that an empty space in the second sealed gap between the covering piece 291a and the upper tray 291, in which a gas is filled, including a inert gas, like helium or nitrogen.

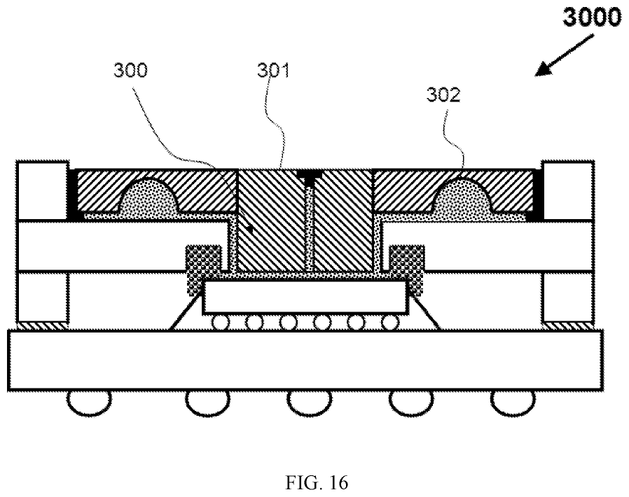

FIG. 16 is a schematic diagram for illustrating another option for a tray design, that is a tray having an opening in its middle region for entirely exposing the flip chip, and a ring-form notch in an extending wing of a heat spreader of a lidded flip chip package. The numerical symbol 3000 in FIG. 16 designates a lidded flip chip package of one embodiment of the present disclosure, in which the numerical symbols 300 designates an opening formed in a middle region of the tray, a middle element 301 of a heat spreader is mounted in the opening 300, and the 302 designates a ring-form notch in the extending wing of the heat spreader. It is noted that the opening 300 is for the middle element 301 to thermally contact with the flip chip, and the ring-form notch 302 is for the extending wing to become more flexible.

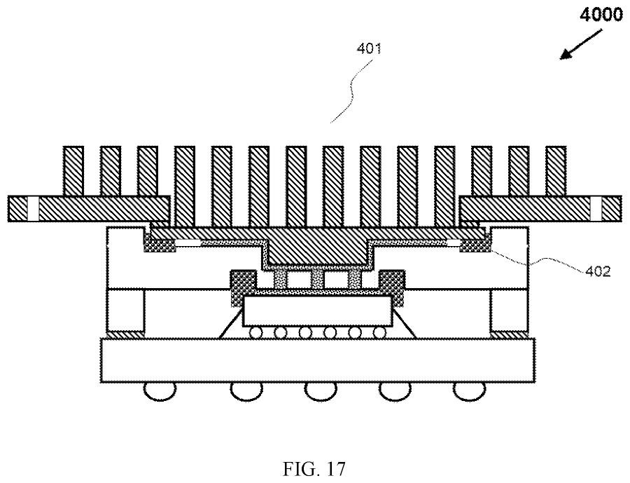

FIG. 17 is a schematic diagram for illustrating that the heat spreader is a heat sink or other cooling pieces and the second sealing ring is a rubber ring. The numerical symbol 4000 in FIG. 17 designates a lidded flip chip package in a field application of one embodiment of the present disclosure, in which the numerical symbols 400 designates a heat sink and the 401 designates a rubber sealing ring.

Although the present disclosure is described in some details for illustrative purpose with reference to the specific embodiments and drawings, it is apparent that many other modifications and variations may be made without departing from the spirit and scope of the present disclosure.

What is claimed is:

1. A lidded flip chip package, comprising:
a substrate, a flip chip mounted on the substrate, and a lid mounted on the substrate and over the flip chip; the lid including: a top piece with an upper side and a lower side, a foot, a tray with a bottom, a first sealing ring, a second sealing ring and a heat spreader; wherein
the first sealing ring is mounted at the lower side of the top piece so as to form a first sealed gap between the flip chip and the lid; the tray is formed at the upper side of the top piece, in which the heat spreader is mounted; the second sealing ring is placed at a peripheral edge region between the heat spreader and the tray so as to form a second sealed gap between them;
wherein a plurality of through-holes are formed through the bottom of the tray so as to connect the first sealed gap with the second sealed gap; and
wherein a thermal interface material having fluidity is completely filled in the first sealed gap and at least partially filled in the second sealed gap.

2. The lidded flip chip package of claim 1, wherein the tray is a two-step tray, whose bottom includes a base-step portion as a portion of the bottom inside the first sealing ring and a second-step portion as a portion of the bottom outside the first sealing ring, and the heat spreader includes a middle element positioned over the base step portion and an extending wing positioned over the second step portion.

3. The lidded flip chip package of claim 1, wherein the tray is a ring-form of tray, and the heat spreader is a ring-form of covering piece, which is mounted in the ring-form of tray so as to form the second sealed gap.

4. The lidded flip chip package of claim 1, wherein the tray is a double sided tray, including an upper tray and a lower flipped tray.

5. The lidded flip chip package of claim 1, wherein an opening is formed in a middle region of the bottom of the tray, the heat spreader includes a middle element and an extending wing, and the middle element is positioned in the opening and over the flip chip.

6. The lidded flip chip package of claim 1, wherein the second sealing ring is a ring-form of adhesive material or a ring-form of rubber material clamped between the heat spreader and the bottom of the tray.

7. The lidded flip chip package of claim 1, wherein one or more openings are formed in the second sealing ring and a filter material is arranged adjacent to the openings.

8. The lidded flip chip package of claim 1, wherein the lid further includes a ring-form of notch at an upper side of the bottom of the tray and around the first sealing ring.

9. The lidded flip chip package of claim 1, wherein the lid further includes a ring-form of notch at the lower side of its top piece, in which the first sealing ring is mounted.

10. The lidded flip chip package of claim 1, wherein the lidded flip chip package further includes a piece of thermally conductive material in the first sealed gap, including a sheet with a plurality of through-holes or slots, a pattern of wire or a mesh.

11. The lidded flip chip package of claim 1, wherein the lid further includes a ring-form of notch at an upper side of the bottom of the tray.

12. The lidded flip chip package of claim 1, wherein the lidded flip chip package further includes a plurality of thermally conductive elements, like a bundle or rope of graphite fibers, which are vertically aligned in one or more of the plurality of through-holes in the bottom of the tray so as to directly connect the flip chip with the heat spreader.

13. The lidded flip chip package of claim 1, wherein the lid further includes one or more filling holes with plugs for filling or withdrawing a liquid thermal interface material into or outside the first and second sealed gaps and for keeping the heat spreader in place.

14. The lidded flip chip package of claim 1, wherein the first sealing ring seals a peripheral edge region at a top surface of the flip chip.

15. The lidded flip chip package of claim 1, wherein the first sealing ring seals a peripheral region around the flip chip and at a top surface of the substrate.

16. The lidded flip chip package of claim 1, wherein the foot of the lid includes a plurality of pins.

17. The lidded flip chip package of claim 1, wherein the foot of the lid consists of a piece of impregnated porous material or mesh with an adhesive or resin, including a pre-impregnated fiberglass.

18. The lidded flip chip package of claim 1, wherein the foot with an adhesive is used as the first sealing ring.

19. The lidded flip chip package of claim 1, wherein the first sealing ring is the foot with an adhesive, the first sealed gap includes a cavity around the flip chip, and the plurality of through-holes are arranged in a peripheral region around the flip chip.

20. The lidded flip chip package of claim 1, wherein the heat spreader includes a middle element, which is a vapor chamber, a heat pipe or a piece of material with high thermal conductivity.

21. The lidded flip chip package of claim 1, wherein the heat spreader includes a separate middle element and a covering sheet.

22. The lidded flip chip package of claim 1, wherein the heat spreader is a heat sink or other cooling pieces and the second sealing ring is a rubber ring.

23. A lid allowing for a thermal interface material having fluidity in a lidded flip chip package, comprising:
a top piece with an upper side and a lower side, a foot, a tray with a bottom and a rim, a first sealing ring, a second sealing ring and a heat spreader; wherein
the tray is formed at the upper side of the top piece; the first sealing ring is mounted at the lower side of the top piece; the heat spreader is mounted inside the tray through the second sealing ring, which also seals a peripheral edge region between the tray and the heat spreader so as to form a sealed gap between them; and a plurality of through-holes are formed in a portion of the bottom of the tray inside the first sealing ring.

24. The lid of claim 23, wherein the tray is a two-step tray, a double sided tray or a ring-form of tray.

25. The lid of claim 23, wherein an opening is formed in a middle region of the bottom of the tray, and the heat spreader includes a middle element and an extending wing, the middle element positioned in the opening and over the flip chip.

26. The lidded flip chip package of claim 23, wherein the heat spreader includes a middle element, an extending wing and a filling hole.

27. The lidded flip chip package of claim 23, wherein one or more openings are formed through the second sealing ring and a filter ring is arranged inside and adjacent to the second sealing ring.
